(19) United States
(12) Patent Application Publication
(10) Pub. No.: US 2002/0080590 A1
(43) Pub. Date: Jun. 27, 2002

(54) Printed circuit board arrangement for printed circuits with electronic components

(75) Inventor: Ralf Bauermeister, Nellmersbach (DE)

Correspondence Address: GUDRUN E. HUCKETT, P.O. BOX 3187, ALBUQUERQUE, NM, 87190, US

(73) Assignee: Murr-Elektronik Gesellschaft mit beschrankter, Oppenweiler (DE)

(21) Appl. No.: 10/025,716

(22) Filed: Dec. 18, 2001

(30) Foreign Application Priority Data
Dec. 21, 2000 (DE) 10063801.5

(51) Int. Cl. H05K 1/11; H05K 1/14

(52) U.S. Cl. 361/803

(57) ABSTRACT

A printed circuit board arrangement for printed circuits with electronic components has a first board having a first electric partial circuit and having a first edge formed as a first contact comb with successively arranged first projections and first cutouts. A second board having a second electric partial circuit and having a second edge formed as a second contact comb with successively arranged second projections and second cutouts is provided, wherein the second contact comb is configured to be complementary to the first contact comb. The first and second boards are combined to form a complete circuit with the first and second boards substantially positioned in a common plane. The first projections engage captively the second cutouts, and the second projections engage captively the first cutouts.

### BACKGROUND OF THE INVENTION

1. Field of the Invention

The invention relates to a printed circuit board arrangement for printed circuits with electronic components, wherein a first board comprises a first partial electric circuit and a second board comprises a second partial electric circuit and the boards are connected with one another by a contact strip for forming a complete circuit, wherein an edge of one board forms a part of the contact strip.

2. Description of the Related Art

It is known to configure complex electronic circuits in modular configurations wherein each partial circuit can have correlated therewith its own board. For forming the complete circuit, the boards are connected with one another mechanically and electrically, wherein, for example, a main board supports a socket into which the edge of a board to be connected thereto is inserted, the edge forming a plug strip. Such plug-in connections are known not only in the PC technology.

In manufacturing, production lines are usually monitored and controlled by one or several control centers, wherein the control centers are connected by a bus with the individual peripheral devices. The peripheral device is controlled, for example, by a power output stage and a bus adaptor.

The peripheral devices are sold by the industry as terminal devices, independent of which bus system is to be used for controlling the device. Accordingly, independent of the bus system, the power output stage remains the same. However, suitable bus adaptors must be connected upstream. They are connected by known plug strips. However, this type of connection causes frequent disruptions because it cannot be mechanically loaded and, electrically, is susceptible to failure. Moreover, a plug strip requires a considerable amount of space which undesirably increases the required size of the configuration. When a monolithic board is chosen for obtaining a mechanically strong connection with high electrical contact safety, a monolithic board with a power output stage must be provided for each bus system; this is very costly and requires many components.

### SUMMARY OF THE INVENTION

It is an object of the present invention to provide a printed circuit board arrangement for printed circuits with electronic components which forms an electrically secure, mechanically highly loadable connection of a minimal size of the configuration.

In accordance with the present invention, this is achieved in that the contact strip at the edge of the board is configured as a first contact comb with successively arranged projections and cutouts, that on the edge of the other board a second contact comb having a configuration complementary to the first contact comb is provided, that the boards are connected with one another positioned approximately in a common plane, wherein the projections of the first contact comb mesh with the cutouts of the second contact comb and vice versa, and wherein a projection is captively received in a cutout.

To configure the edge of the board with successively arranged projections and cutouts for forming a contact comb is space-saving but still enables largesurface area connections by means of a correspondingly long configuration of the projections and deep configuration of the cutouts. The boards are positioned approximately in a common plane, wherein the projections of the first contact comb mesh with the cutouts of the second contact comb and vice versa. Since a projection is secured captively in a cutout, a mechanical connection is provided. When all projections are captively secured in their cutouts, the printed circuit board arrangement forms a quasi monolithic board.

The contact comb is preferably a part of the printed circuit of the boards to be joined and thus forms at the same time the electrical connection of the two partial circuits to form the complete circuit. Since the thickness of the contact comb corresponds to the thickness of the board, the height of the thus formed contact strip is within the range of the height of the components on the board. The printed circuit board arrangement has a low profile with regard to its height which is determined only by the height of the components.

When the projections have an electric contact path on each longitudinal side and when the longitudinal edges of the boards, in particular, the longitudinal edges of the projections, are additionally copper-clad, not only a connection on the large face of the board will result upon soldering, but the solder material, as a result of the copper cladding on the edge and the capillary action of the solder material, will also enter the gap between neighboring projections and thus provide a large surface area connection. This provides a mechanically very strong connection which is also vibration-resistant and shock-resistant. Moreover, as a result of the large surface area electrical connection, a greater current conduction is possible in comparison to a simple plug-in configuration. Corrosion of the electrical connectors does not occur. Moreover, as a function of the length of the edge, almost any number of contacts can be provided. A contact comb cannot only be provided on the narrow side of a board but alternatively also on the longitudinal side of a board. This provides a correspondingly larger number of contacts. Preferably, a contact comb is formed across the entire length of the board edge.

In order to configure the board connection of the present invention so as to be protected against accidentally mismatched connections, the contact combs can be provided with a code. In this connection, it is expedient to configure the shape of individual projections and cutouts on one board in different ways.

### BRIEF DESCRIPTION OF THE DRAWING

In the drawing:

FIG. 1 is a plan view onto a printed circuit board arrangement comprised of two boards with partial electric circuit;

FIG. 2 is a schematic plan view onto the printed circuit board arrangement in the joined state;

FIG. 3 shows a detail III of FIG. 1 on an enlarged scale.

### DESCRIPTION OF THE PREFERRED EMBODIMENTS

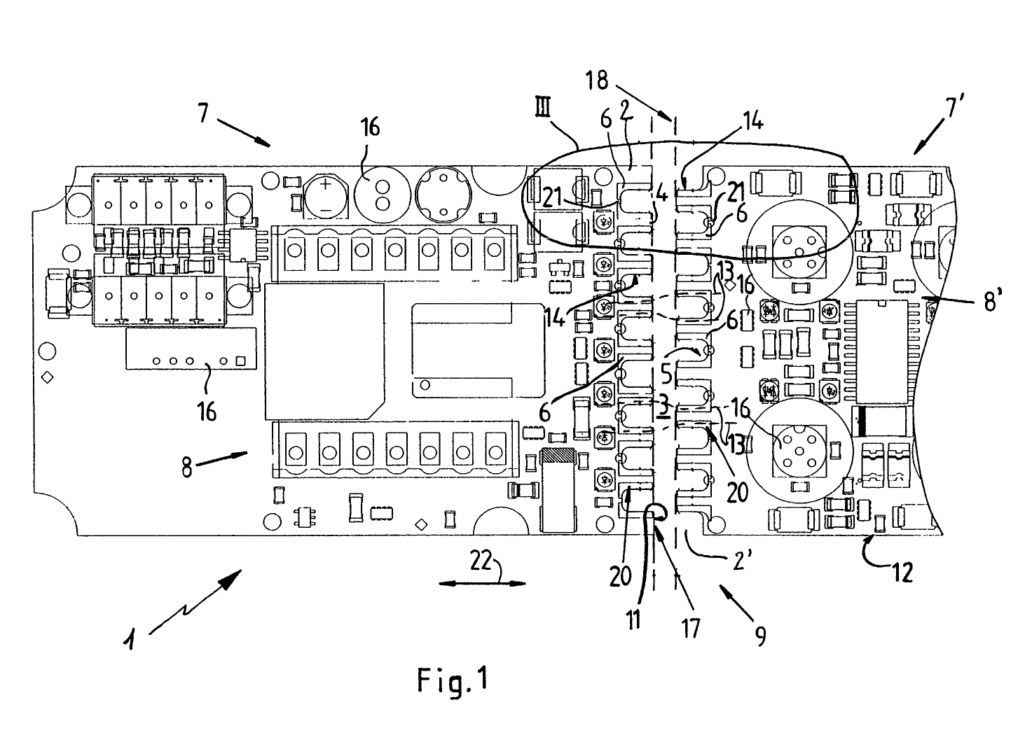

The printed circuit board arrangement 1 illustrated in FIG. 1 is formed of two combined or joined boards 7, 7′, each supporting a partial electric circuit 8, 8′. Each board 7, 7′ is comprised of an insulating support which preferably is copper-clad on both sides. On each side a printed circuit is provided which serves for connecting electronic components 16, such as processors, memory chips, power chips and the like, supported on the boards 7, 7′. For realizing a modular configuration, the partial circuit 8 of the first board 7, for example, can be configured as a power output stage while the partial circuit 8′ of the second board 7′ can be a control circuit or the like which connects the power output stage 8, for example, with a control bus or the like. The modular individual boards 7, 7′ are configured in regard to their functionality such that, upon mechanical and electrical joining of the two boards 7, 7′, their partial circuits 8, 8′ form a complete circuit 9.

The boards 7, 7′ of the printed circuit board arrangement 1 are substantially rectangular in shape wherein, in the illustrated embodiment, they are connected mechanically and electrically by means of contact combs 2, 2′ provided on their narrow side 3, respectively.

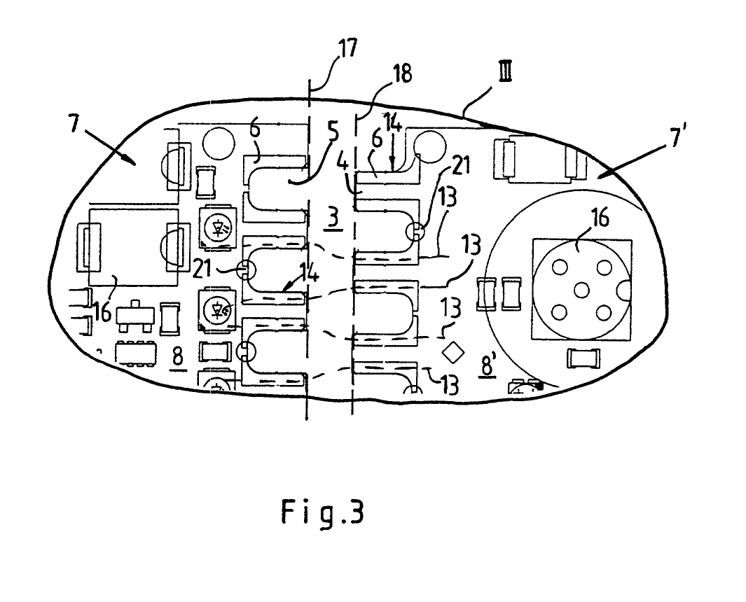

Each contact comb 2, 2′ is comprised of a series of projections 4 delimiting therebetween cutouts 5. The width of a projection 4 measured in the longitudinal direction of the board edge 17, 18 corresponds approximately to the width of a cutout 5. As illustrated particularly in FIG. 3, on the top side as well as on the bottom side of each board 7, 7′ electric strip conductors 6 are formed which extend in the joining direction 22 on the longitudinal sides or joining edges 14 of the substantially rectangular projections 4. The copper cladding or coating on the large faces of the boards has been separated by milled slots 21 so that for each projection 4 on each large face of the board 7, 7′ two electric strip conductors 6 are formed, respectively. When joining the boards, the directly adjacently positioned strip conductors 6, after soldering, provide electrical contact paths 13 from one board 7 to the other board 7′.

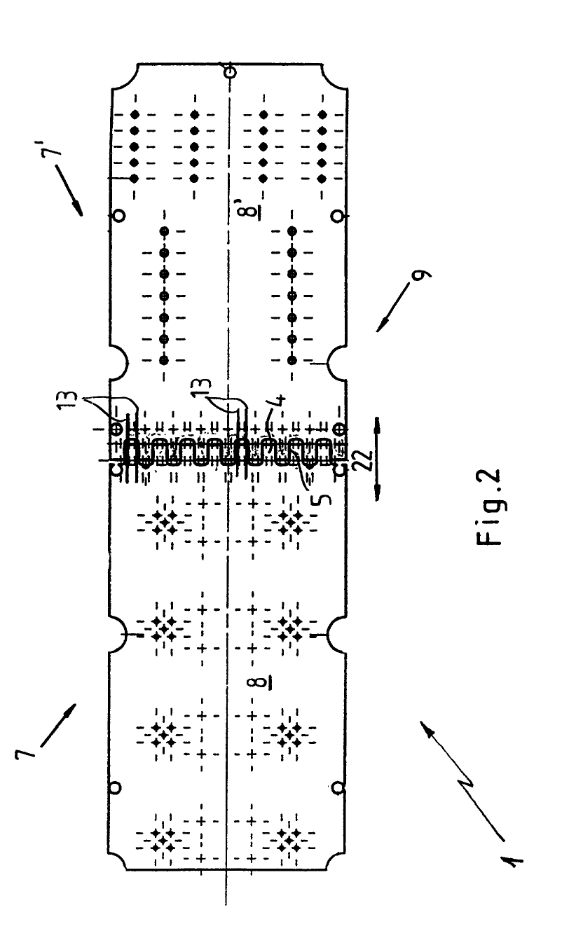

As illustrated in FIG. 1, on the edge 17 of the board 7 a first contact comb 2, extending in the longitudinal direction of the edge 17 and comprising successively arranged projections 4 and cutouts 5, is provided. The board edge 18 of the board 7′ to be connected thereto has a second contact comb 2′ which is of a complementary configuration relative to the first contact comb 2. As illustrated in FIG. 1, one projection 4, in the joining direction 22, is positioned precisely aligned with a cutout 5 so that upon joining a projection 4 is received in a cutout 5, as illustrated in FIG. 2. The bottom of the cutout 5 is rounded so that a gap remains between the end of the projection 4 and the bottom of the cutout 5; this gap remains free of solder material after soldering and ensures the electrical separation of the strip conductors 6.

The two boards 7, 7′ are joined with one another while being positioned substantially in a common plane wherein the strip conductors 6 of the contact combs are parts of the printed circuit 8, 8′ of the board or are electrically connected with the printed circuit. Preferably, the contact comb 2, 2′ is a monolithic part of the board 7, 7′ so that the thickness of the contact comb, i.e., the thickness of the projections 4, matches the thickness of the board 7, 7′. Preferably, the cutouts 5 are milled into the copper-coated board so that the projections 4 remain therebetween. In the area of the contact combs 2, 2′, the copper cladding is removed by milling, etching or the like for forming the electric strip conductors 6. This provides on each longitudinal edge or side of the projections 4 an electrically separated contact path 6, wherein the contact paths of the two large faces of the board can be connected to one another electrically by applying a copper coating onto the longitudinal edges of the projections 4. Applying a copper coating on the longitudinal edges has the advantage that during soldering the solder material also enters the gap between two projections by capillary action and provides a mechanically strong, electrically highly loadable connection. Advantageously, the connection is produced automatically in a wave soldering (flow soldering) bath.

In order to prevent an erroneous joining of boards which are not match to one another, the contact combs are coded. For this purpose, the projections 4 and/or the cutouts 5 can be provided entirely or partially with undercuts, can taper conically, or the longitudinal edges or sides can be shaped so as to deviate from the joining direction.

While specific embodiments of the invention have been shown and described in detail to illustrate the inventive principles, it will be understood that the invention may be embodied otherwise without departing from such principles.

What is claimed is:

1. A printed circuit board arrangement for printed circuits with electronic components, comprising:
a first board (7) having a first electric partial circuit (8) and having a first edge (17) formed as a first contact comb (2) with successively arranged first projections (4) and first cutouts (5);
a second board (7′) having a second electric partial circuit (8′) and having a second edge (18) formed as a second contact comb (2′) with successively arranged second projections (4′) and second cutouts (5′), wherein the second contact comb (2′) is configured to be complementary to the first contact comb (2);
wherein the first and second boards (7, 7′) are combined to form a complete circuit (9) with the first and second boards (7, 7′) substantially positioned in a common plane;
wherein the first projections (4) engage captively the second cutouts (5′) and the second projections (4′) engage captively the first cutouts (5).

2. The printed circuit board arrangement according to claim 1, wherein the first and second contact combs (2, 2′) are parts of the printed circuit of the first and second boards (7, 7′), respectively.

3. The printed circuit board arrangement according to claim 1, wherein the first and second contact combs (2, 2′) are monolithic parts of the first and second boards (7, 7′), respectively.

4. The printed circuit board arrangement according to claim 1, wherein a thickness (11) of the first and second contact combs (2, 2′) matches a thickness (12) of the first and second boards (7, 7′), respectively.

5. The printed circuit board arrangement according to claim 1, wherein the first and second projections (4,4′) have longitudinal sides (14), respectively, and wherein each one of the longitudinal sides (14) supports an electrically isolated contact lead (6).

6. The printed circuit board arrangement according to claim 5, wherein the first and second edges (17, 18) have a copper coating.

7. The printed circuit board arrangement according to claim 6, wherein the longitudinal sides (14) of the first and second projections (4, 4′) have a copper coating.

8. The printed circuit board arrangement according to claim 1, wherein the first and second contact combs (2, 2′) are connected by soldering.

9. The printed circuit board arrangement according to claim 1, wherein the first and second contact combs (2, 2′) are coded.

10. The printed circuit board arrangement according to claim 1, wherein the first and second projections (4, 4′) have undercuts.

11. The printed circuit board arrangement according to claim 10, wherein the first and second cutouts (5, 5′) have undercuts.

12. The printed circuit board arrangement according to claim 1, wherein the first and second cutouts (5, 5′) have undercuts.

13. The printed circuit board arrangement according to claim 1, wherein the first and second projections (4, 4′) are substantially rectangular and have longitudinal sides (14) providing joining edges extending in a joining direction (22) of the first and second boards (7, 7′).

14. The printed circuit board arrangement according to claim 1, wherein the first and second contact combs (2, 2′) extend over the entire length of the first and second edges (17, 18), respectively.

15. The printed circuit board arrangement according to claim 1, wherein the electrical isolation is provided by milled slots (21).
